(19) United States
(12) Patent Application Publication
(10) Pub. No.: US 2026/0246368 A1
(43) Pub. Date: Aug. 20, 2026

(54) Power converter integrated circuit with connection fault detection function

(71) Applicant: Chengdu Monolithic Power Systems Co., Ltd., Chengdu (CN)

(72) Inventors: Wei-Heng Wang, New Taipei City (TW); Hsin Chen, New Taipei City (TW); Yong Deng, Chengdu (CN); Haitang Wang, Chengdu (CN); Pengjie Lai, Cupertino, CA (US)

(21) Appl. No.: 19/540,284

(22) Filed: Feb. 13, 2026

(30) Foreign Application Priority Data
Feb. 17, 2025 (CN) 202510170357.2

(51) Int. Cl. H02M 1/32

(52) U.S. Cl. CPC H02M 1/32

(57) ABSTRACT

An integrated circuit for a power conversion circuit includes: an input terminal, an output terminal, a reference ground terminal, a switching terminal, and an abnormal connection event detection circuit. The input terminal is configured to receive an input voltage. The output terminal is configured to provide an output voltage. The reference ground terminal is configured to be coupled to a reference ground voltage. The switching terminal is configured to be coupled to a common connection node of the high-side switch and the low-side switch. The high-side switch and the low-side switch are coupled in series between the output terminal and the reference ground terminal. The abnormal connection event detection circuit is configured to detect an abnormal connection event in the power conversion circuit before the startup of the power conversion circuit, and generate an abnormal connection warning signal for indicating the abnormal connection event based on detecting that the abnormal connection event occurs.

### CROSS-REFERENCE

The present application claims priority to, and the benefit of, Chinese application No. 202510170357.2 filed on Feb. 17, 2025, which is incorporated herein by reference in its entirety.

### TECHNICAL FIELD

The present application relates to power converters, and more particularly to fault self-detection circuits and methods for protecting circuit components from abnormal connections.

### BACKGROUND

Generally, a power conversion circuit typically leverages characteristics of an energy storage element such as a capacitor or an inductor. By controlling the operation of controllable power switches (e.g., metal-oxide-semiconductor field-effect transistors, MOSFETs) through control signals (e.g., pulse-width modulation (PWM) signals) to switch them on or off at high frequency, these circuits enable the storage components to alternately store and release electrical energy. Through this energy flow process, power converters transform input voltage into a stable output voltage to supply various application devices. Through the process of energy flow, the power converter can convert the input voltage into another stable output voltage to supply power to various application devices.

In a soldering process of a power management system incorporating a power conversion circuit, it is crucial to ensure accurate soldering of related power devices (for example, a power switch and a power inductor, etc.) in a power converter. Therefore, an effective fault detection scheme must be established to identify abnormal connections such as short circuits or cold solder joints in power devices, thereby guaranteeing the performance and reliability of the power management system.

### SUMMARY

Based on the above problems, the present disclosure provides an integrated circuit for a power conversion circuit, including: an input terminal, an output terminal, a reference ground terminal, a switching terminal and an abnormal connection event detection circuit. The input terminal is configured to receive an input voltage. The output terminal is configured to provide an output voltage. The reference ground terminal is configured to be coupled to a reference ground voltage. The switching terminal is configured to be coupled to a common connection node of the high-side switch and the low-side switch. The high-side switch and the low-side switch are coupled in series between the output terminal and the reference ground terminal. The abnormal connection event detection circuit is configured to detect an abnormal connection event in the power conversion circuit before the startup of the power conversion circuit, and generate an abnormal connection warning signal for indicating the abnormal connection event based on detecting that the abnormal connection event occurs.

### BRIEF DESCRIPTION OF DRAWINGS

To more clearly illustrate the technical solutions in the embodiments of the present application, the following briefly introduces the drawings required for describing the embodiments or the prior art. It is evident that the drawings described below are merely some embodiments of the present application. For those skilled in the art, other drawings may be obtained based on these drawings without creative labor.

FIG. 1 illustrates a block diagram of a power management system 100 according to an embodiment of the present invention.

FIG. 2 illustrates an exemplary circuit diagram of a power stage of a power converter in the power management system shown in FIG. 1.

FIG. 3 illustrates a flowchart of a method 300 for detecting an abnormal connection event according to an embodiment of the present invention.

FIG. 4 illustrates an exemplary circuit diagram of a sensing circuit according to an embodiment of the present invention.

FIG. 5 illustrates a schematic diagram of a circuit for determining whether an L open-circuit event or an LS short-circuit event has occurred in method 300.

FIG. 6 illustrates a circuit schematic for determining whether an HS short-circuit event has occurred in method 300.

FIG. 7 illustrates a schematic diagram of a circuit for determining whether an HS open-circuit event has occurred in method 300.

FIG. 8 illustrates a flowchart of a method 800 for detecting an abnormal connection event according to an embodiment of the present invention.

FIG. 9 illustrates a circuit schematic for determining whether an HS open-circuit event, an LS short-circuit event, or an L open-circuit event has occurred in method 800.

### DETAILED DESCRIPTION

Various embodiments of the present invention will now be described. In the following description, certain specific details are included, such as exemplary circuits and exemplary values for these circuit components, to provide a thorough understanding of the embodiments. However, one skilled in the relevant art will recognize, that the disclosure can be performed without one or more of the specific details, or with other methods, components, materials, etc. In other instances, well-known structures, materials, processes or operations are not shown or described in detail to avoid obscuring aspects of the disclosure.

Throughout the specification and claims, the phrases “in an embodiment,” “in some embodiments,” “in an implementation,” and “in some implementations” used include combinations and sub-combinations of the various features described herein, as well as variations and modifications thereof. These phrases used herein do not necessarily refer to the same embodiment, although they may. It will be understood by those skilled in the art that the meanings of the above terms do not necessarily limit the terms, but merely provide illustrative examples for the terms. Note that when a component is “connected to” or “coupled to” another component, this means that the component is directly connected to or coupled to the other component, or indirectly connected to or coupled to the other component via another component. Particular features, structures or characteristics may be included in an integrated circuit, an electronic circuit, a combinational logic circuit or other suitable components that provide the described functionality. Furthermore, it should be understood that the drawings provided herewith are for explanation purposes to those of ordinary skill in the art and the drawings are not necessarily drawn to scale.

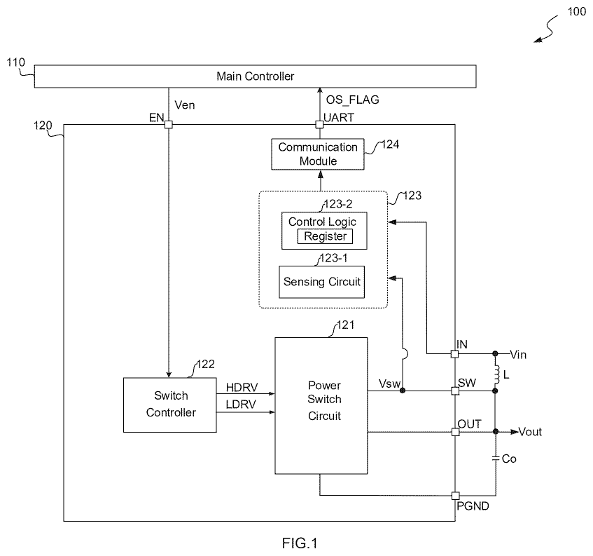

FIG. 1 is a block diagram illustrating a power management system 100 according to an embodiment of the present invention. Referring to FIG. 1, the power management system 100 includes a power converter 120 and a main controller 110.

As shown in FIG. 1, the power converter 120 includes a power switch circuit 121, a switch controller 122, and an abnormal connection event detection circuit 123. In addition, the power converter 120 further includes connection terminals such as an input terminal IN, an output terminal OUT, a switching terminal SW, an enable terminal EN, a communication terminal UART, and a reference ground terminal PGND. For simplicity of description, other unrelated circuit components and terminals are omitted herein.

The switching terminal SW is configured to be coupled to one end of a power inductor L, and the input terminal IN is configured to be coupled to the other end of the power inductor L. The switching component(s) in the power switch circuit 121 is configured to be turned on or off under the control of driving signal(s) (e.g., shown in the figure as a pair of signals HDRV and LDRV with opposite logic states) to increase or decrease an inductor current flowing through the power inductor L, thereby converting an input voltage Vin into an output voltage Vout. The output terminal OUT is configured to provide the output voltage Vout. An output capacitor Co is coupled between the output terminal OUT and the reference ground terminal PGND for filtering and smoothing the output voltage Vout. Hereinafter, the power switch circuit 121, the power inductor L and the output capacitor Co are referred to as a power stage.

The switch controller 122 may generate switch driving signal(s) based on a feedback signal representative of the output voltage Vout of the power converter 120. For example, in an embodiment of a PWM control method such as voltage control and current control, the switch controller 122 may amplify a difference between the feedback signal and a reference signal, and then compare the amplified difference signal with a ramp signal, to generate the switch driving signal(s). It should be understood that the switch controller 122 may be implemented using any suitable control mode and circuit configuration capable of controlling the power stage. A topology structure and a control mode of the switch controller 122 are not limited in the present invention.

In an embodiment, the abnormal connection event detection circuit 123, the switch controller 122 and the power switch circuit 121 may be embedded in a power management integrated circuit (PMIC). It should be understood that the packaging form of the power converter 120 is not limited in the present disclosure. For example, in another embodiment, the power switch circuit 121 may be disposed outside the PMIC.

In an embodiment, the abnormal connection event detection circuit 123 is configured to be enabled in response to the PMIC being powered on (e.g., receiving the input voltage Vin), and to determine whether an abnormal connection event has occurred in the power stage based on a power stage signal received from the power stage, thereby generating an abnormal connection warning signal OS_FLAG. For example, the power stage signal here may include the voltage Vsw on the common connection node of the switching transistors in the power switching circuit 121 or the output voltage Vout on the output terminal OUT.

As shown, the abnormal connection event detection circuit 123 includes a sensing circuit 123-1 for sensing power stage signals and a control logic circuit 123-2 for controlling the abnormal connection event detection process. In addition, the abnormal connection event detection circuit 123 may further include a register dedicated to recording the abnormal connection event. When it is determined that the abnormal connection event occurs, a bit value of the register may be set to a first value (for example, 1).

In an embodiment, the power converter 120 may further include a communication module 124 for transmitting the abnormal connection warning signal OS_FLAG to an external main controller 110 (e.g., via the communication terminal UART) in response to the bit value in the abnormal connection event register being set to the first value. The communication protocols supported by the communication module 124 includes, but is not limited to, a Universal Asynchronous Receiver-Transmitter (UART) protocol, a Serial Peripheral Interface (SPI) protocol, and an Inter-Integrated Circuit (I2C) protocol, which is not limited in the present disclosure.

In response to the abnormal connection warning signal OS_FLAG not received from the power converter 120 (i.e., indicating that the abnormal connection event detection circuit 123 has not detected an abnormal connection event), the main controller 110 generates a corresponding enable signal Ven (e.g., a signal in an enable logic state (e.g., logic high)) and sends the enable signal Ven to the enable terminal EN. This enables the PMIC when no abnormal connection event is detected, thereby initiating a startup process (e.g., soft start) of the PMIC. Thus, through the internally configured fault self-detection function, connection faults can be promptly detected before the PMIC starts up (i.e., before the PMIC receives the enable signal Ven via the enable terminal EN), and the faulty PMIC can be disabled to prevent its incorrect operation from damaging downstream application devices.

In an embodiment, the main controller 110 may be an electronic control unit (ECU) or a host including such an ECU. In another embodiment, the main controller 110 may be a micro control unit (MCU) or a host including the MCU. The present disclosure is not limited thereto. The main controller 110 may also be embedded in a separate PMIC, or may be embedded in the same PMIC as the power converter 120.

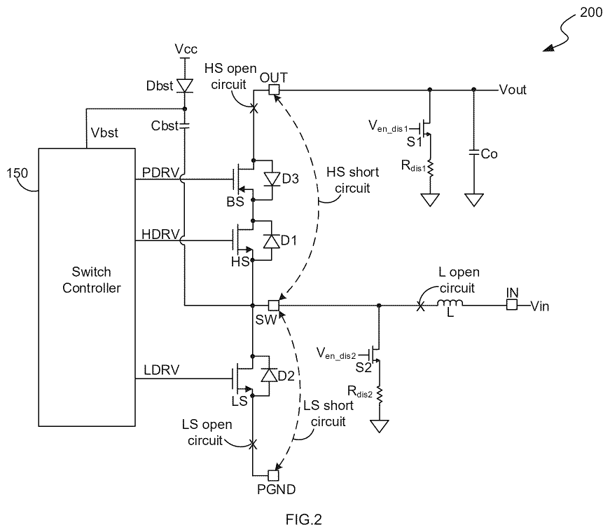

FIG. 2 illustrates an exemplary circuit diagram of a power stage 200. Referring to FIG. 2, the power stage 200 includes a high-side switch (also referred to as a first switch) HS, a low-side switch (also referred to as a second switch) LS, a power inductor L, and an output capacitor Co. In FIG. 2, the power stage 200 is implemented using a circuit structure of a boost converter. Those skilled in the art should understand that, in another embodiment, the power stage 200 may also employ other switching conversion circuit structures, such as a buck conversion circuit structure, a buck-boost conversion circuit structure, etc. The present disclosure is not limited thereto.

Referring to FIG. 2, the power inductor L has a first terminal and a second terminal. The first terminal is coupled to the input terminal IN to receive the input voltage Vin. The high-side switch HS includes a first terminal, a second terminal and a control terminal. In addition, the high-side switch HS further includes a body diode D1. The first terminal of the high-side switch HS is coupled to the second terminal of the power inductor L, the second terminal of the high-side switch HS is coupled to the output terminal OUT for providing the output voltage Vout, and the control terminal of the high-side switch HS is configured to receive a first driving signal HDRV from a switch controller 150. The high-side switch HS may be turned on and off under the control of the first driving signal HDRV. The low-side switch LS includes a first terminal, a second terminal and a control terminal. In addition, the low-side switch further includes a body diode D2. The first terminal of the low-side switch LS is coupled to the second terminal of the power inductor L, the second terminal of the low-side switch LS is coupled to the reference ground terminal PGND, and the control terminal of the low-side switch LS is configured to receive a second driving signal LDRV from the switch controller 150. The low-side switch LS may be turned on and off under the control of the second driving signal LDRV. The second terminal of the high-side switch HS is coupled to the first terminal of the low-side switch LS to form a common connection node, and the switching terminal SW is configured to be coupled to this common connection node. One terminal of the output capacitor Co is coupled to the output terminal OUT, and the other terminal is coupled to the reference ground terminal PGND.

In an embodiment, each of the high-side switch HS and the low-side switch LS includes a controllable transistor. For example, FIG. 2 exemplarily shows the high-side switch HS and the low-side switch LS as metal-oxide-semiconductor field-effect transistors (MOSFETs). In the embodiment shown in FIG. 2, the high-side switch HS and the low-side switch LS are NMOS devices. In the embodiment, the power converter may further include a voltage bootstrap circuit (e.g., a bootstrap capacitor Cb and a bootstrap diode Db coupled between the bootstrap supply input voltage Vb and the switching terminal SW) to ensure that the high-side switch HS can be turned on accurately. It should be understood that the present invention is not limited thereto. For example, the high-side switch HS may be a PMOS, and the low-side switch LS may be an NMOS. The following description uses the example where both the high-side switch HS and the low-side switch LS are NMOS.

In an embodiment, as shown in FIG. 2, the power stage may further include a protection switch BS configured to be coupled between the output terminal OUT and the high-side switch HS. In an embodiment, the protection switch BS also includes a controllable transistor, such as a MOSFET. In the embodiment shown in FIG. 2, the protection switch BS is a PMOS. In an embodiment, the connection between the protection switch BS and the high-side switch HS is configured such that their body diodes (e.g., the body diode D2 and the body diode D3) are connected in a back-to-back way. This arrangement enables the disconnection of the electrical connection between the output terminal OUT and the switching terminal SW when both the high-side switch HS and the protection switch BS are turned off. The protection switch BS has a first terminal, a second terminal and a control terminal for receiving a protection control signal PDRV. During the connection fault detection process or soft start process, when the high-side switch HS is turned on, the protection control signal PDRV can control the protection switch BS to operate in the variable resistance region to regulate the current flowing through the high-side switch HS. During normal boost operation, the protection control signal PDRV may control the protection switch BS to remain in an ON state (e.g., operating in the saturation region).

In addition, the power stage 200 may further include a forced discharge circuit, coupled between the output terminal OUT and the switching terminal SW, configured to discharge the output terminal OUT and the switching terminal SW when the forced discharge circuit is enabled. In an embodiment, the forced discharge circuit includes a first forced discharge sub-module coupled between the output terminal OUT and the reference ground terminal PGND, and a second forced discharge sub-module coupled between the switching terminal SW and the reference ground terminal PGND. In an embodiment, as shown in the figure, the first forced discharge sub-module includes a switching component S1 and a resistor Rdis1 connected in series, and the second forced discharge sub-module includes a switching component S2 and a resistor Rdis2 connected in series. The switching component S1 and the switching component S2 may be, for example, MOSFETs, each having a first terminal, a second terminal and a control terminal. The control terminals of the switching components S1 and S2 are respectively configured to receive discharge enable signals Ven_dis1 and Ven_dis2, and are respectively turned on under the control of the corresponding discharge enable signals, so that the voltages of the switching terminal SW and the output terminal OUT are respectively pulled down to the reference ground voltage when the switching components S1 and S2 being turned on.

As shown in FIG. 2, an abnormal connection event in the power stage may include one of the following conditions: a condition where the switching terminal SW is shorted to the output terminal OUT (which may also be referred to as HS short circuit), a condition where the switching terminal SW is shorted to the reference ground terminal PGND (which may also be referred to as LS short circuit), a condition where the power inductor L is disconnected from the switching terminal SW or a condition where the power inductor L is disconnected from the input terminal IN (which may also be referred to as L open circuit), a condition where the high-side switch HS is disconnected from the output terminal OUT or a condition where the high-side switch HS is disconnected from the switching terminal SW (which may also be referred to as HS open circuit), a condition where the low-side switch LS is disconnected from the reference ground terminal PGND or a condition where the low-side switch LS is disconnected from the switching terminal SW (which may also be referred to as LS open circuit), etc. When one or more of these conditions occur, the power converter 120 will generate an abnormal connection warning signal (e.g., OS_FLAG) and send the abnormal connection warning signal to the main controller 110, and the main controller 110 responds by disabling the power converter 120.

In the normal boost operation and in the condition where no abnormal connection event occurs, the protection switch BS remains in the ON state, and the high-side switch HS and the low-side switch LS are turned on and off respectively under the control of the first driving signal HDRV and the second driving signal LDRV. This causes the energy storage component (e.g., the power inductor L) to alternately store and release electric energy, thereby converting the input voltage Vin into the output voltage Vout. Specifically, the switch controller 150 may provide the first driving signal HDRV and the second driving signal LDRV to the control terminals of the high-side switch HS and the low-side switch LS, respectively. The first driving signal HDRV has a set logic state (e.g., logic high) for driving the high-side switch HS to turn on and a reset logic state (e.g., logic low) for driving the high-side switch HS to turn off. The second driving signal LDRV has a set logic state (e.g., logic high) for driving the low-side switch LS to turn on and a reset logic state (e.g., logic low) for driving the low-side switch LS to turn off. When the first driving signal HDRV is logic low and the second driving signal LDRV is logic high, the high-side switch HS is turned off, the low-side switch LS is turned on, and a current flows from the input terminal VIN through the power inductor L, the switching terminal SW and the low-side switch LS to charge the power inductor L. When the first driving signal HDRV is logic high and the second driving signal LDRV is logic low, the high-side switch HS is turned on, the low-side switch LS is turned off, and a current flows from the input terminal IN to the output terminal OUT and the output capacitor Co through the power inductor L, the switching terminal SW and the high-side switch HS.

The power converter shown in FIG. 1 can determine whether an abnormal connection event has occurred before the PMIC starts up and begins operation through the abnormal connection event detection circuit built in the PMIC. It can then preemptively disable the faulty PMIC to prevent further damage to the system caused by the incorrect operation of the defective chip.

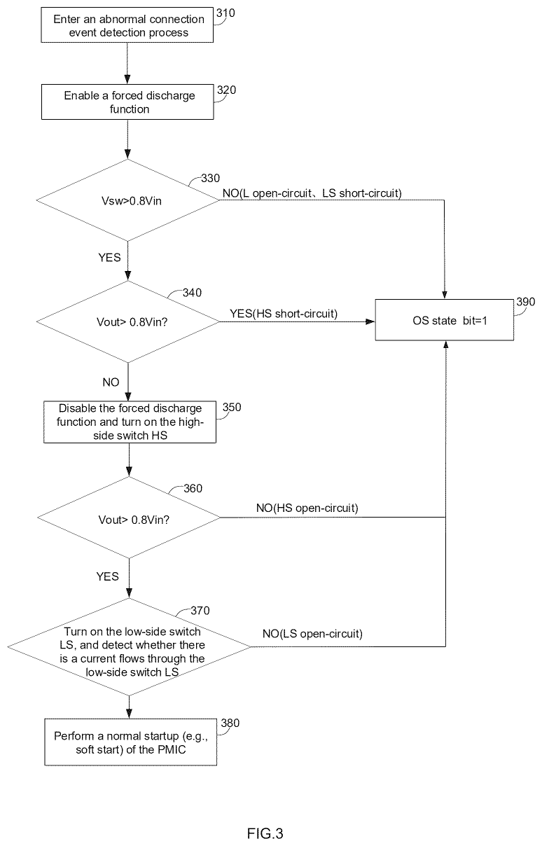

FIG. 3 illustrates a flowchart of a method 300 for detecting an abnormal connection event according to an embodiment of the present invention. The method 300 in FIG. 3 will be described in conjunction with FIGS. 1, 2, and 4-7. For purposes of explanation, it will be assumed that the power management system has the configuration shown in FIG. 1.

Referring to FIG. 3, the method 300 includes the following steps 310-390.

Step 310: Enter an abnormal connection event detection process. For example, the abnormal connection event detection circuit 123 is enabled in response to receiving the input voltage Vin from the input terminal IN, thereby entering the abnormal connection event detection process. In an embodiment, the method 300 is performed prior to the soft-start of the PMIC 120, while the high-side switch HS, the low-side switch LS, and the protection switch BS are all held in the off state.

Step 320: Enable a forced discharge function. In an embodiment, the control logic circuit 123-2 in the abnormal connection event detection circuit 123 may send a first forced discharge enable signal Ven_dis1 and a second forced discharge enable signal Ven_dis2 to the control terminals of the switch S1 and the switch S2 respectively, to turn on the switch S1 and the switch S2 respectively, thereby connecting the output terminal OUT and the switching terminal SW to the reference ground GND, so that a switching voltage Vsw on the switching terminal SW and the output voltage Vout are reduced to zero volts (or close to zero volts).

Step 330: Compare the switching voltage Vsw on the switching terminal SW with a reference voltage Vref, and determine whether the switching voltage Vsw is greater than the reference voltage Vref. In an embodiment, this step may be used to determine whether an L open-circuit event or an LS short-circuit event has occurred.

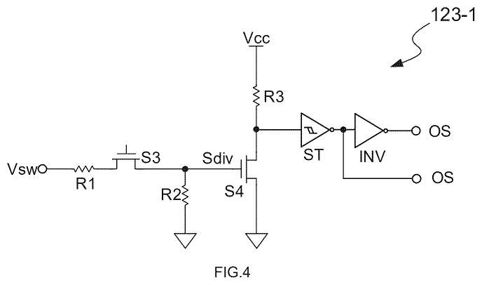

In an embodiment, the sensing circuit 123-1 in the abnormal connection event detection circuit 123 is configured to compare the switching voltage Vsw with the reference voltage Vref and output a sensing signal OS to indicate whether an abnormal connection event has occurred. In an embodiment, the reference voltage Vref may be set to a value close to but less than the input voltage Vin. For example, the reference voltage Vref may be set to 0.8Vin. In another embodiment, the switching voltage Vsw and the reference voltage Vref may be scaled down proportionally before comparison. FIG. 4 illustrates an exemplary circuit diagram of a sensing circuit 123-1 according to an embodiment of the present invention. In the embodiment shown in FIG. 4, the proportionally scaled reference voltage Vref may be set to the turn on threshold RDS(on) of the MOS transistor (for example, RDS(on)=0.7 V). Based on this, the switching voltage Vsw may be proportionally scaled by adjusting the resistance value of the voltage divider resistor, thereby enabling comparison of the scaled switching voltage Vsw with 0.7V.

As shown in FIG. 4, the sensing circuit 123-1 includes MOSFETs S3 and S4, resistors R1-R3, a Schmitt trigger ST and an inverter INV, with the interconnections illustrated in FIG. 4.

As shown in FIG. 4, the sensing circuit 123-1 receives the switching voltage Vsw on the switching terminal SW at an input terminal and outputs the sensing signal OS at an output terminal for indicating whether an abnormal connection event has occurred. When the MOS transistor S3 is turned on, the resistors R1 and R2 divide the switching voltage Vsw, and generate a voltage division signal Sdiv=Vsw*R2/(R1+R2) on the resistor R2 for controlling the MOS transistor S4. When the voltage division signal Sdiv exceeds a turn-on threshold RDS(on) of the MOS transistor S4(for example, RDS (on)=0.7 V), the MOS transistor S4 is turned on. Based on actual comparison requirements, the output of the Schmitt trigger ST or the output of the inverter INV may be used as the sensing signal OS to indicate whether an abnormal connection event has occurred. For example, in step 330, the sensing circuit 123-1 shown in FIG. 4 may output the output of the Schmitt trigger ST as the sensing signal OS.

It should be understood that the circuit diagram of the sensing circuit 123-1 in FIG. 4 is merely provided as an example, and those skilled in the art may design any suitable circuit to compare the switching voltage Vsw with the reference voltage Vref.

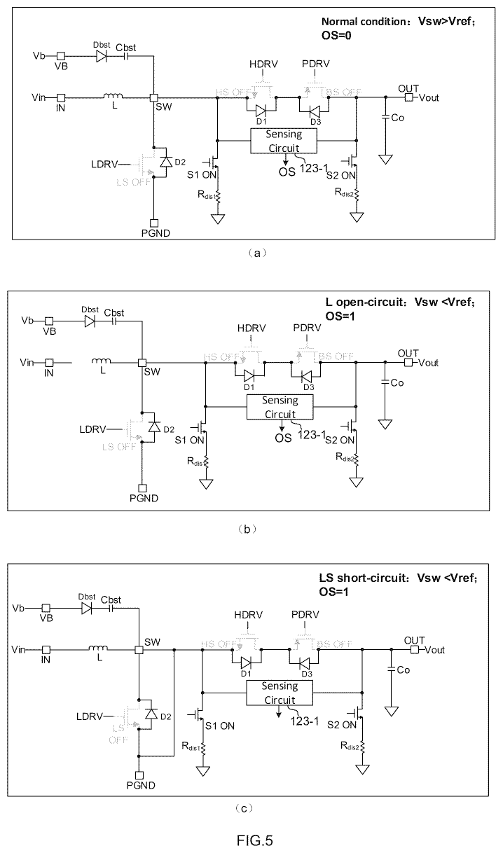

FIG. 5 illustrates a circuit schematic for determining whether an L open-circuit event or an LS short-circuit event has occurred in method 300.

As shown in the sub-diagram (a) in FIG. 5, in a case where no L open-circuit event or LS short-circuit event occurs (i.e., under normal case), the switching terminal SW is coupled to the input terminal IN through the power inductor L. The switching voltage Vsw on the switching terminal SW is equal to the input voltage Vin and exceeds the reference voltage Vref, i.e., Vsw>Vref. The sensing circuit 123 outputs OS=0, indicating that no relevant abnormal connection event has occurred.

As shown in the sub-diagram (b) in FIG. 5, if an L open-circuit event occurs (for example, as shown in the drawing, the inductor L is disconnected from the input terminal IN), since the forced discharge function keeps ON, the switching voltage Vsw=0, which is less than the reference voltage Vref, i.e., Vsw<Vref, the sensing circuit 123 outputs OS=1, indicating that an abnormal connection event has occurred, for example, an L open-circuit event has occurred.

As shown in the sub-diagram (c) in FIG. 5, if an LS short-circuit event occurs (for example, as shown in the drawing, the switching terminal SW is shorted to the reference ground terminal PGND), the switching terminal SW is coupled to the reference ground terminal PGND through a short circuit path. At this time, the switching voltage is close to zero volts, which is less than the reference voltage Vref, i.e., Vsw<Vref. The sensing circuit 123 outputs OS=1, indicating that an abnormal connection event has occurred, for example, an LS short-circuit event has occurred.

With continued reference to FIG. 3, when it is determined that the switching voltage Vsw is greater than the reference voltage Vref (330=YES), indicating that no LS short-circuit event or L open-circuit event occurs. The method proceeds to step 340 to continue to determine whether other types of abnormal connection events occur. Otherwise (330=NO), this indicates that an LS short-circuit event or an L open-circuit event has occurred, the method proceeds to step 390.

Step 340: Compare the voltage Vout on the output terminal OUT with the reference voltage Vref, and determine whether the output voltage Vout is greater than the reference voltage Vref. In an embodiment, this step may be used to determine whether an HS short-circuit event has occurred.

For example, in step 340, the sensing circuit 123-1 in the abnormal connection event detection circuit 123 may compare the voltage Vout with the reference voltage Vref based on the sensing circuit 123-1 shown in FIG. 4, and the sensing circuit 123-1 shown in FIG. 4 may output the output of the inverter INV as the sensing signal OS.

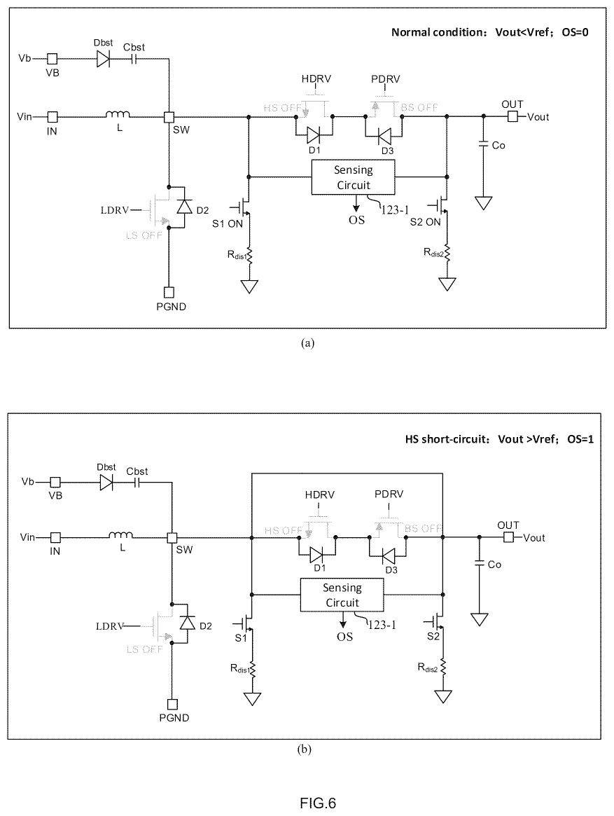

FIG. 6 illustrates a circuit schematic for determining whether an HS short-circuit event has occurred in method 300.

As shown in the sub-diagram (a) in FIG. 6, in a case where no HS short-circuit event occurs, since the forced discharge function keeps ON, at this time, the output terminal is connected to the reference ground through the switch S2 and the resistor Rdis2. At this point, the output voltage Vout is close to zero volts, which is less than the reference voltage Vref, i.e., Vout<Vref. The sensing circuit 123 outputs OS=0, indicating that no HS short-circuit event has occurred.

As shown in the sub-diagram (b) in FIG. 6, if an HS short-circuit event occurs, the output terminal OUT is coupled to the input terminal IN through a short circuit path, so that the voltage on the output terminal OUT exceeds the reference voltage Vref, i.e., Vout>Vref. The sensing circuit 123 outputs OS=1, indicating that an abnormal connection event has occurred, for example, an HS short-circuit event has occurred.

Referring back to FIG. 3, when it is determined in step 340 that the output voltage Vout is less than the reference voltage Vref (340=NO), indicating that no HS short-circuit event has occurred, the method proceeds to step 350 to continue to determine whether other types of abnormal connection events occur. Otherwise (340=YES), the method proceeds to step 390.

Step 350: Disable the forced discharge function and turn on the high-side switch HS. In this step, there will be a current flowing from the input terminal IN to the output terminal OUT. In an embodiment, the control logic circuit 123-2 in the abnormal connection event detection circuit 123 may control a magnitude of the protection control signal PDRV provided to the protection switch BS to make the protection switch BS to operate in the variable resistance region, thereby controlling a magnitude of the current flowing through the high-side switch HS.

Step 360: Compare the voltage Vout on the output terminal OUT with the reference voltage Vref, and determine whether the output voltage Vout is greater than the reference voltage Vref. In an embodiment, this step may be used to determine whether an HS open-circuit event has occurred.

For example, in step 360, the sensing circuit 123-1 in the abnormal connection event detection circuit 123 may compare the voltage Vout with the reference voltage Vref based on the sensing circuit 123-1 shown in FIG. 4, and the sensing circuit 123-1 shown in FIG. 4 may lead out the output of the Schmitt trigger ST as the sensing signal OS.

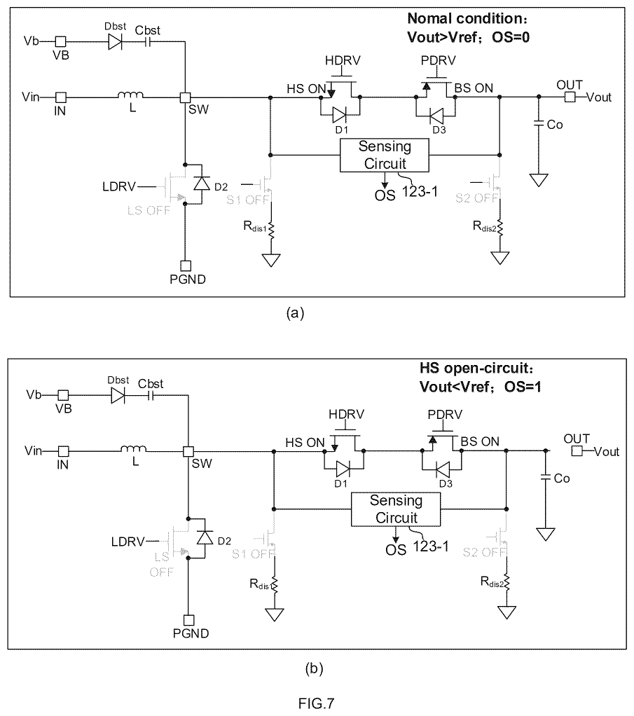

FIG. 7 shows a circuit schematic for determining whether an HS open-circuit event has occurred in method 300.

As shown in the sub-diagram (a) in FIG. 7, in a case where no HS open-circuit event occurs, since the forced discharge function is disabled (as shown, S1 and S2 are turned off) and the high-side switch HS and the protection switch BS are turned on, there will be a current flowing from the input terminal IN to the output terminal OUT and charging the output capacitor Co. After a predetermined time, the output voltage Vout will become greater than the reference voltage Vref, causing the sensing circuit 123 to output OS=0.

As shown in the sub-diagram (b) in FIG. 7, if an HS open-circuit event occurs (for example, as shown in the drawing, the high-side switch HS is disconnected from the output terminal OUT), the output terminal OUT will be disconnected from the input terminal IN. Since the output terminal OUT is discharged in the previous step, the voltage Vout on the output terminal OUT is equal to 0, which is less than the reference voltage Vref, that is, Vout<Vref. The sensing circuit 123 outputs OS=1, indicating that an abnormal connection event has occurred, for example, an HS open-circuit event has occurred.

Referring back to FIG. 3, when step 360 determines that the output voltage Vout is greater than the reference voltage Vref, (360=YES), indicating that no HS open-circuit event has occurred, the method proceeds to step 370. Otherwise (360=NO), the method proceeds to step 390.

According to an embodiment of the present invention, after the step 360, the method 300 may further include a step 370 for detecting whether the switching terminal SW is disconnected from the reference ground terminal PGND (e.g., an LS open-circuit event). In this step, the low-side switch LS is turned on, and detection is performed to determine whether there is a current flows through the low-side switch LS. If no current is detected flowing through the low-side switch LS, the sensing signal OS=1 is output, indicating that an abnormal connection event has occurred, such as an LS open-circuit event has occurred. In this embodiment, the abnormal connection event detection circuit 123 may further include a current sensing circuit for detecting whether the current flows through the low-side switch LS.

Step 380: Perform a normal startup (e.g., soft start) of the PMIC.

Step 390: Set the bit value of the abnormal connection event register to a first value (for example, 1). For example, the control logic circuit 123-2 in the abnormal connection event detection circuit 123 may set the bit value of the abnormal connection event register to the first value based on the signal OS=1. Further, the communication module 124 may generate the abnormal connection warning signal OS_FLAG in response to the bit value being set to the first value, and send the abnormal connection warning signal OS_FLAG to the external main controller 110 through the communication terminal UART. The main controller 110 will not enable the faulty PMIC.

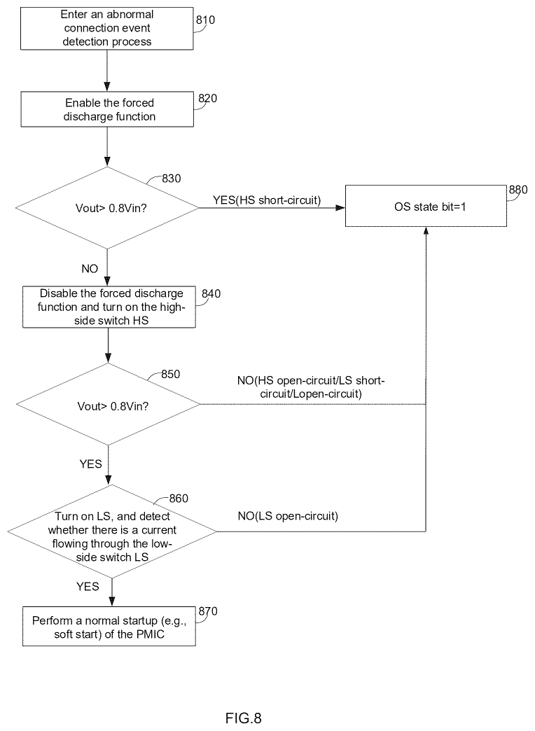

FIG. 8 shows a flowchart of a method 800 for detecting an abnormal connection event according to another embodiment of the present invention. The method 800 in FIG. 8 will be described in conjunction with FIGS. 1, 2, and 9. For the purpose of explanation, it will be assumed that the power management system has the form shown in FIG. 1.

Referring to FIG. 8, the method 800 includes the following steps 810-880.

Step 810: Enter an abnormal connection event detection process. For example, the abnormal connection event detection circuit 123 is enabled in response to receiving the input voltage Vin from the input terminal IN, thereby entering the abnormal connection event detection process. In an embodiment, the method 800 is performed before the soft-start of the PMIC 120, at which time the high-side switch HS, the low-side switch LS, and the protection switch BS are all held in the off state.

Step 820: Enable the forced discharge function. In an embodiment, the control logic circuit 123-2 in the abnormal connection event detection circuit 123 may send the first forced discharge enable signal Ven_dis1 and the second forced discharge enable signal Ven_dis2 respectively to the control terminals of the switch S1 and the switch S2, to turn on the switch S1 and the switch S2 respectively. This connects the output terminal OUT and the switching terminal SW to the reference ground GND, thereby reducing the switching voltages Vsw on the switching terminal SW and the output voltage Vout to zero volts (or close to zero volts).

Step 830: Compare the output voltage Vout at the output terminal OUT with the reference voltage Vref, and determine whether the output voltage Vout is greater than the reference voltage Vref. In an embodiment, this step may be used to determine whether an HS short-circuit event has occurred.

For example, in step 830, the sensing circuit 123-1 in the abnormal connection event detection circuit 123 may compare the voltage Vout with the reference voltage Vref based on the sensing circuit 123-1 shown in FIG. 4, and the sensing circuit 123-1 shown in FIG. 4 may output the inverted signal from the inverter INV as the sensing signal OS.

The schematic circuit diagram for determining whether the HS short-circuit event has occurred in step 830 may be understood with reference to FIG. 6. Details are not described hereinafter.

When step 830 determines that the output voltage Vout is less than the reference voltage Vref (830=NO), it indicates that no HS short-circuit event has occurred. The method proceeds to step 840 to continue to determine whether other types of abnormal connection events have occurred. Otherwise (830=YES), the method proceeds to step 880.

Step 840: Disable the forced discharge function and turn on the high-side switch HS. In this step, there will be a current flowing from the input terminal IN to the output terminal OUT. In an embodiment, the control logic circuit 123-2 in the abnormal connection event detection circuit 123 may control a magnitude of the protection control signal PDRV provided to the protection switch BS. This causes the protection switch BS to operate in the variable resistance region, thereby regulating the magnitude of the current flowing through the high-side switch HS.

Step 850: Compare the voltage Vout on the output terminal OUT with the reference voltage Vref, and determine whether the output voltage Vout is greater than the reference voltage Vref. In an embodiment, this step may be used to determine whether an HS open-circuit event, an LS short event, or an L open-circuit event has occurred.

For example, in step 850, the sensing circuit 123-1 in the abnormal connection event detection circuit 123 may compare the voltage Vout with the reference voltage Vref based on the sensing circuit 123-1 shown in FIG. 4, and the sensing circuit 123-1 shown in FIG. 4 may lead out the output of the Schmitt trigger ST as the sensing signal OS.

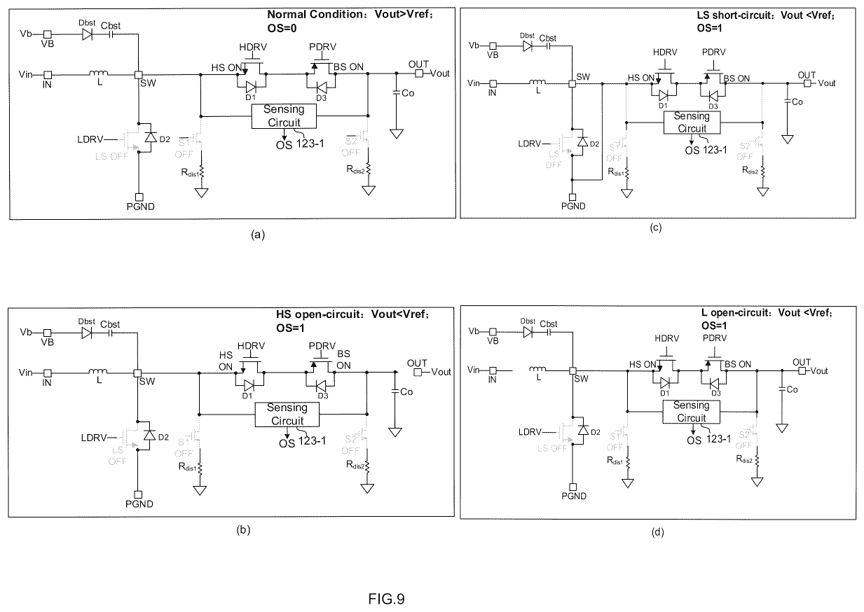

FIG. 9 shows a circuit schematic for determining whether an HS open-circuit event, an LS short event, or an L open-circuit event has occurred in method 800.

As shown in the sub-diagram (a) in FIG. 9, when none of the aforementioned events occur, since the forced discharge function is disabled (as shown, S1 and S2 are turned off) and the high-side switch HS and the protection switch BS are turned on, there will be a current flowing from the input terminal IN to the output terminal OUT through the high-side switch HS and the protection switch BS, and charge the output capacitor Co. After a predetermined time, the output voltage Vout will become greater than the reference voltage Vref, causing the sensing circuit 123 to output OS=0.

As shown in the sub-diagram (b) in FIG. 9, if an HS open-circuit event occurs (for example, as shown in the drawing, the output terminal OUT is disconnected from the input terminal IN), since the output terminal OUT is discharged in the previous step, the voltage Vout=0 on the output terminal OUT is less than the reference voltage, i.e., Vout<Vref. The sensing circuit 123 outputs OS=1, indicating that an abnormal connection event has occurred, for example, an HS open-circuit event has occurred.

As shown in the sub-diagram (c) in FIG. 9, if an LS short-circuit event occurs (e.g., as shown, the switching terminal SW is coupled to the reference ground terminal PGND), the output terminal OUT is connected to the reference ground terminal PGND through a short circuit path of the protection switch BS, the high-side switch HS, and the switching terminal SW between the reference ground terminal PGND. This causes the output voltage to be less than the reference voltage, i.e., Vout<Vref. The sensing circuit 123 outputs OS=1, indicating that an abnormal connection event has occurred, e.g., an LS short-circuit event has occurred.

As shown in sub-diagram (d) in FIG. 9, if an L open-circuit event occurs, since the forced discharge function is disabled, the output terminal OUT is in a floating state. At this point, the output voltage Vout is less than the reference voltage Vref, i.e., the output voltage Vout<Vref. The sensing circuit 123 outputs OS=1, indicating that an abnormal connection event has occurred, for example, an L open-circuit event has occurred.

Referring back to FIG. 8, when step 850 determines that the output voltage Vout is greater than the reference voltage (850=YES), indicating that the aforementioned events have not occurred, the method proceeds to step 860. Otherwise (850=NO), the method proceeds to step 880.

According to an embodiment of the present invention, after the step 850, the method 800 may further include step 860 for detecting whether the switching terminal SW is disconnected from the reference ground terminal PGND (e.g., an LS open-circuit event). In step 860, the low-side switch LS is turned on, and detection is performed to determine whether there is a current flowing through the low-side switch LS. If no current is detected flowing through the low-side switch LS, the sensing signal OS=1 is output, indicating that an abnormal connection event, such as an LS open-circuit event has occurred. In this embodiment, the abnormal connection event detection circuit 123 may further include a current sensing circuit for detecting whether there is a current flow through the low-side switch LS.

Referring back to FIG. 8, when step 860 determines that a current is flowing through the low-side switch LS (860=YES), indicating that no LS open-circuit event has occurred, the method proceeds to step 870. Otherwise (860=NO), the method proceeds to step 880.

Step 870: Perform a normal startup (e.g., soft start) of the PMIC.

Step 880: Set the bit value of the abnormal connection event register to a first value (for example, 1). For example, the control logic circuit 123-2 in the abnormal connection event detection circuit 123 may set the bit value of the abnormal connection event register to the first value based on the signal OS=1. Further, the communication module 124 may generate an abnormal connection warning signal OS_FLAG in response to the bit value being set to the first value, and send the abnormal connection warning signal OS_FLAG to the external main controller 110 through the communication terminal UART. The main controller 110 will not enable the faulty PMIC.

Although FIGS. 3 and 8 show sequential steps, it will be apparent to those skilled in the art that these steps may be performed in any appropriate order, and may perform only some of the steps, which is not limited by the present disclosure.

Thus, the present application discloses a fault self-detection circuit and corresponding method for protecting PMIC circuit components from short-circuit events or open-circuit events or other abnormal connection problems. An abnormal connection event can be detected in a timely manner before the PMIC is formally activated, and the faulty chip can be disabled to avoid further damage caused by incorrect operation damage of the faulty chip, thereby improving the reliability of the PMIC.

It will be appreciated by those skilled in the art that the present disclosure is not limited to that has been particularly shown and described hereinabove. Rather, the scope of the present disclosure is defined by the claims and includes both combinations and sub-combinations of the various features described hereinabove, as well as variations and modifications thereof which would occur to those skilled in the art upon reading the foregoing description and which are not in the prior art.

1. An integrated circuit for a power conversion circuit, comprising:
an input terminal, configured to receive an input voltage,
an output terminal, configured to provide an output voltage,
a reference ground terminal, configured to be coupled to a reference ground voltage, a switching terminal, configured to be coupled to a common connection node of a high-side switch and a low-side switch, wherein the high-side switch and the low-side switch are coupled in series between the output terminal and the reference ground terminal, and
an abnormal connection event detection circuit, configured to detect an abnormal connection event in the power conversion circuit before the power conversion circuit starts up, and to generate an abnormal connection warning signal indicating the detected abnormal connection event.

2. The integrated circuit of claim 1, further comprising:
an enable terminal, configured to receive an enable signal, wherein “before the power conversion circuit starts up” refers to the integrated circuit not having received the enable signal through the enable terminal.

3. The integrated circuit of claim 2, wherein the integrated circuit receives the enable signal through the enable terminal when no abnormal connection event occurs in the power conversion circuit.

4. The integrated circuit of claim 1, wherein the abnormal connection event comprises one or more of the following: the switching terminal being shorted to the output terminal, the switching terminal being shorted to the reference ground terminal, the high-side switch being disconnected from the output terminal, the high-side switch being disconnected from the switching terminal, the low-side switch being disconnected from the reference ground terminal, and the low-side switch being disconnected from the switching terminal.

5. The integrated circuit of claim 4, wherein the switching terminal is configured to be coupled to one end of a power inductor, the input terminal is configured to be coupled to the other end of the power inductor, the high-side switch and the low-side switch are configured to be turned on or off under the control of corresponding control signals, thus to increase or decrease an inductor current flowing through the power inductor, thereby converting the input voltage into the output voltage, and wherein the abnormal connection event further comprises: the switching terminal being disconnected from the power inductor, and the power inductor being disconnected from the input terminal.

6. The integrated circuit of claim 1, further comprising a communication terminal, configured to provide the abnormal connection warning signal to a main controller.

7. The integrated circuit of claim 1, wherein the abnormal connection event detection circuit comprises:
a sensing circuit, configured to compare a switching voltage on the switching terminal or the output voltage on the output terminal with a reference voltage, and further generate a sensing signal based on a comparison result; and
a control logic circuit, configured to generate the abnormal connection warning signal in response to the sensing signal having a set logic state.

8. The integrated circuit of claim 7, further comprising:
a forced discharge circuit, coupled to the output terminal and the switching terminal, and configured to discharge the output terminal and the switching terminal when the forced discharge circuit is enabled.

9. The integrated circuit of claim 8, wherein the forced discharge circuit comprises:
a first forced discharge circuit and a second forced discharge circuit, configured to discharge the output terminal and the switching terminal respectively when the first forced discharge circuit and the second forced discharge circuit are enabled.

10. The integrated circuit of claim 9, wherein the first forced discharge circuit comprises a first switching element and a first discharge resistor coupled in series between the output terminal and the reference ground terminal, and the second forced discharge circuit comprises a second switching element and a second discharge resistor coupled in series between the switching terminal and the reference ground terminal, wherein the first switching element and the second switching element are configured to be turned on in response to a discharge enable signal from the control logic circuit, thereby connecting the switching terminal and the output terminal to the reference ground terminal respectively.

11. The integrated circuit of claim 7, wherein the control logic circuit further comprises a register for recording the abnormal connection event, and wherein the control logic circuit is configured to set a bit value of the register to a first value in response to the sense signal having the set logic state.

12. The integrated circuit of claim 8, wherein the abnormal connection event detection circuit is configured to be enabled in response to the input voltage, thereby entering an abnormal connection event detection process.

13. The integrated circuit of claim 12, wherein during the abnormal connection event detecting process, the control logic circuit is configured to perform one or more of the following steps:
enabling the forced discharge circuit, so as to discharge the output terminal and the switching terminal,
controlling the sensing circuit to compare the switching voltage on the switching terminal with the reference voltage, wherein if the switching voltage is less than the reference voltage, the sensing circuit outputs the sensing signal having the set logic state; if the switching voltage is greater than the reference voltage, the sensing circuit outputs the sensing signal having a reset logic state;
if the switching voltage is greater than the reference voltage, comparing the output voltage with the reference voltage, and determining whether the output voltage is greater than the reference voltage, wherein if the output voltage is greater than the reference voltage, the sensing circuit outputs the sensing signal having the set logic state, and if the output voltage is less than the reference voltage, the sensing circuit outputs the sensing signal having the reset logic state;
if the output voltage is less than the reference voltage, disabling the forced discharge circuit and turning on the high-side switch, and determining whether the output voltage is greater than the reference voltage, wherein if the output voltage is greater than the reference voltage, the sensing circuit outputs the sensing signal having the reset logic state, and if the output voltage is less than the reference voltage, the sensing circuit outputs the sensing signal having the set logic state.

14. The integrated circuit of claim 12, wherein during the abnormal connection event detection process, the control logic circuit is configured to perform one or more of the following steps:
enabling the forced discharge circuit, so as to discharge the output terminal, controlling the sensing circuit to compare the output voltage with the reference voltage, wherein if the output voltage is greater than the reference voltage, the sensing circuit outputs the sensing signal having the set logic state; if the output voltage is less than the reference voltage, the sensing circuit outputs the sensing signal having a reset logic state;
if it is determined that the output voltage is less than the reference voltage, disabling the forced discharge circuit and turning on the high-side switch, and determining whether the output voltage is greater than the reference voltage, wherein if the output voltage is greater than the reference voltage, the sensing circuit outputs the sensing signal having the reset logic state, and if the output voltage is less than the reference voltage, the sensing circuit outputs the sensing signal having the set logic state.

15. The integrated circuit of claim 13, further comprising a protection switch coupled between the high-side switch and the output terminal, wherein the protection switch and the high-side switch are connected such that a body diode in the high-side switch and a body diode in the protection switch are coupled in series in a back-to-back way.

16. The integrated circuit of claim 15, wherein when the forced discharge circuit is disabled and the high-side switch is turned on, the protection switch is configured to work in a variable resistance region, thereby controlling a magnitude of a current flowing through the high-side switch.

17. The integrated circuit of claim 13, further comprising a current sensing circuit, wherein the control logic circuit is further configured to:
turn off the high-side switch and turn on the low-side switch, and control the current sensing circuit to detect whether there is a current flow through the low-side switch,
wherein if it is detected that there is a current flow through the low-side switch, the current sensing circuit outputs the sensing signal having the reset logic, and if no current flowing through the low-side switch is detected, the current sensing circuit outputs the sensing signal having the set logic state.
